(19) United States
(12) Patent Application Publication
(10) Pub. No.: US 2007/0146993 A1
(43) Pub. Date: Jun. 28, 2007

(54) Method, apparatus and computer system for enhancement of thermal energy transfer

(75) Inventors: Rajiv K. Mongia, Fremont, CA (US); Himanshu Pokharna, San Jose, CA (US); Sridhar V. Machiroutu, Santa Clara, CA (US)

Correspondence Address: INTEL CORPORATION;c/o INTELLEVATE, LLC, P.O. BOX 52050, MINNEAPOLIS, MN, 55402, US

(73) Assignee: INTEL CORPORATION

(21) Appl. No.: 11/317,710

(22) Filed: Dec. 23, 2005

(51) Int. Cl. H05K 7/20

(52) U.S. Cl. 361/695; 361/687

(57) ABSTRACT

Some embodiments of a method, apparatus and computer system are described for enhancing the transfer of heat from electronic components. The computer system includes a housing and an apparatus. The apparatus includes a heat transfer enhancement module internally coupled to an electronic device and positioned with respect to an electronic component, wherein the heat transfer enhancement module includes an air mover to enhance heat transfer of the electronic component, and wherein the apparatus enhances cooling of a primary heat exchanger. In embodiments, the air mover is a blower fan, a piezoelectric fan, and/or a membrane fan. The apparatus provides enhanced heat transfer for the system. Other embodiments are described.

### BACKGROUND

1. Technical Field

Some embodiments of the invention generally relate to cooling systems. More specifically, some embodiments relate to an apparatus, computer system and method for enhancing the transfer of heat.

2. Discussion

In recent years, electronic components and systems have been made to operate at faster speeds. These developments, such as processors with one or more cores for computing systems, have been made to meet increasing demands for better performance. Thus, these demands have led to a decrease in the weight and an increase in the density of components. These factors lead to increases in heat generation. Particularly in mobile computing environments, these factors can lead to overheating, which may negatively affect performance, and can significantly reduce battery life.

The above-mentioned factors increase the need for effective cooling of electronic components. FIG. 1 illustrates a conventional configuration of a cooling system. A computer system 100 includes a housing 101, a central processing unit (CPU) 102, and one or more electronic components 104. The CPU 102 is typically in contact with a heat exchanger 106 which is in close proximity to a fan 108. The fan 108 forces air out of the computer system 100 by passing through the heat exchanger 106. The fan 108 thus serves to establish a direction for air flow, shown at 110, within which external air comes into the system at one or more of the air intakes 112.

As previously mentioned, increases in operating temperatures may negatively affect the performance of the computer system. Therefore, there is a need for an enhanced cooling system for computer systems. In particular, there is a need for cooling systems that, at least, are more efficient at transferring heat from electronic components and skins within computer systems.

### BRIEF DESCRIPTION OF THE DRAWINGS

Various advantages of embodiments of the present invention will become apparent to one of ordinary skill in the art by reading the following specification and appended claims, and by referencing the following drawings, in which:

FIG. 1 illustrates a example of conventional cooling in a computer system;

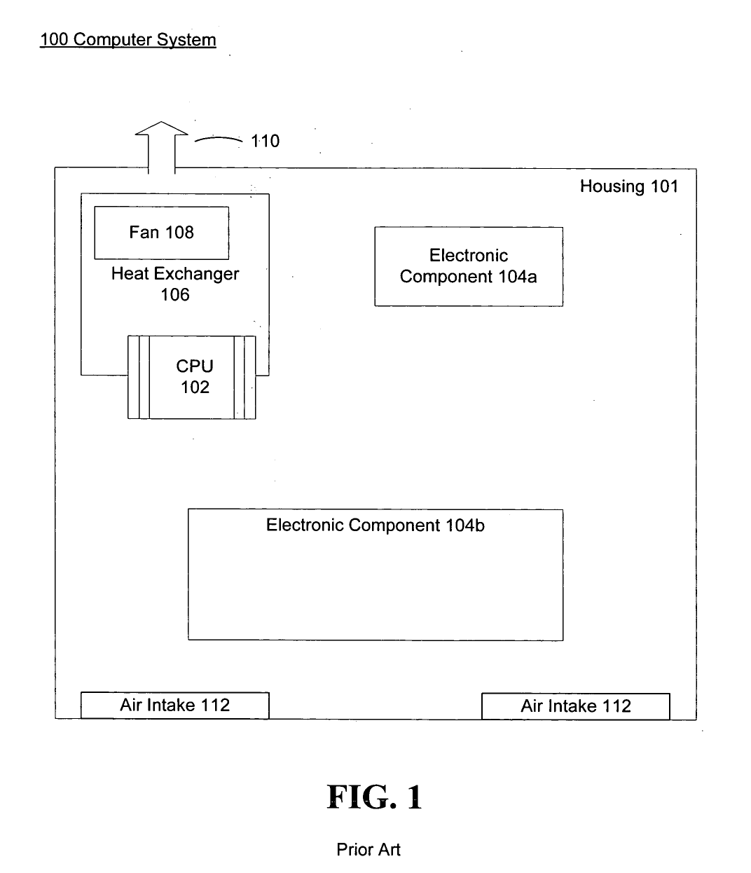

FIG. 2 illustrates an example of an enhanced cooling apparatus in a cooling system according to some embodiments of the invention;

FIG. 3 illustrates an example of a heat transfer enhancement module according to some embodiments of the invention;

FIG. 4 illustrates examples of fan types according to some embodiments of the invention;

FIG. 5 illustrates an example of a heat transfer enhancement module according to some embodiments of the invention; and

FIG. 6 illustrates an example of the installation and use of the heat transfer enhancement module according to some embodiments of the invention.

### DETAILED DESCRIPTION

Reference is made to some embodiments of the invention, examples of which are illustrated in the accompanying drawings. While the invention will be described in conjunction with the embodiments, it will be understood that they are not intended to limit the invention to these embodiments. On the contrary, the invention is intended to cover alternatives, modifications and equivalents, which may be included within the spirit and scope of the invention as defined by the appended claims. Moreover, in the following detailed description of the invention, numerous specific details are set forth in order to provide a thorough understanding of the invention. However, the invention may be practiced without these specific details. In other instances, well-known methods, procedures, components and circuits have not been described in detail as not to unnecessarily obscure aspects of the invention.

Some embodiments of the invention are directed to a method, apparatus and computer system for enhancing the transfer of heat from electronic components. Some embodiments of a method, apparatus and computer system are described for enhancing the transfer of heat from electronic components. The computer system includes a housing and an apparatus. The apparatus may include a heat transfer enhancement module internally coupled to an electronic device and positioned with respect to an electronic component, wherein the heat transfer enhancement module may include an air mover to enhance heat transfer of the electronic component, and wherein the apparatus enhances cooling of a primary heat exchanger.

In some embodiments of the invention, the enhancement provided by one or more HTE modules may allow for an increase in the thermal design power (TDP) of the computer system, or more specifically of an electronic component. More specifically, the use of the HTE module may increase the heat transfer coefficient between the electronic component (or optionally, a spreader) and the air within the computer system. This may result, according to some embodiments of the invention, in more heat being dissipated.

In embodiments, the air mover is a blower fan, a piezoelectric fan, and/or a membrane fan. The apparatus provides enhanced heat transfer for the system. Other embodiments are described. Indeed, reference in the specification to an embodiment or some embodiments of the invention means that a particular feature, structure or characteristic described in connection with the embodiment is included in at least one embodiment of the invention. Thus, the appearances of the phrase “in one embodiment” or “according to an embodiment” appearing in various places throughout the specification are not necessarily all referring to the same embodiment.

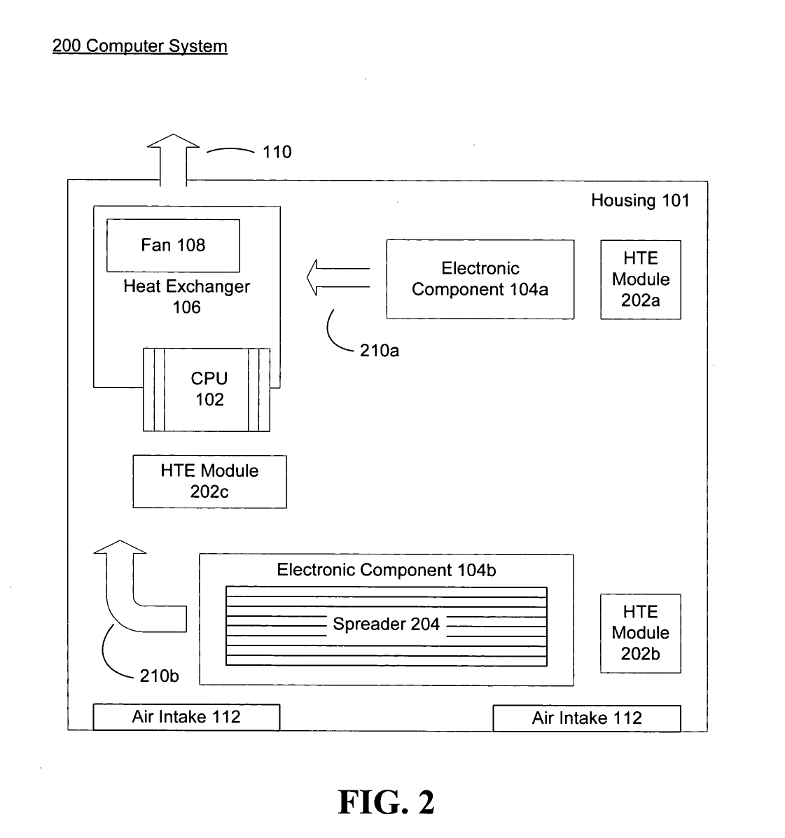

FIG. 2 illustrates an example of an enhanced cooling apparatus in a cooling system according to some embodiments of the invention. According to some embodiments of the invention, a computer system 200 may include a housing 101, a central processing unit (CPU) 102, and one or more electronic components 104, shown as 104a and 104b. The CPU 102 may be in contact with a heat exchanger 106 which may further include a fan 108. The fan 108 may force air out of the computer system 200. The fan 108 may serve to establish a direction for air flow, shown at 110, within which external air comes into the system at air intake 112.

Furthermore, in some embodiments, the transfer of heat may be enhanced by the addition of one or more heat transfer enhancement (HTE) modules 202, shown as 202a, 202b, and 202c. In operation, according to some embodiments, the HTE module 202a may provide, in the locality of the electronic component 104a, an increase in the velocity of the air over the electronic component 104a. In some embodiments of the invention, the HTE module may provide a zone of high velocity air. The air flow over the electronic component 104a is indicated at 210a. The increase in air velocity may move a larger amount of heat off the electronic component 104a and into the air flow established by the fan 108. In alternative embodiments, the HTE module 202a may be positioned to enhance an air flow in a different direction, such as toward the housing 101 and/or away from any other components of the computer system 200. In yet other embodiments, the HTE module 202 may not increase the velocity of air, but rather alter the shape or volume of the velocity air and/or thermal boundary layer in order to increase the heat dissipation from the electronic component.

According to some embodiments of the invention, an apparatus for the enhancement of heat transfer may include the HTE module 202. The HTE module may be internally coupled to an electronic device and positioned with respect to an electronic component, according to some embodiments. Furthermore, in some embodiments, the electronic component 104 may include a spreader or heat exchanger, as is described elsewhere herein.

In some embodiments, the HTE module may be integrated into the spreader or the heat exchanger. In addition, according to some embodiments, the HTE module may be coupled to the electronic component.

Furthermore, in some embodiments of the invention, the electronic component may be one of a central processing unit, a processor, a memory, a hard drive, a network card, a video graphics card, a motherboard, and/or a heat source. In some embodiments, the computer system may be an electronic device such as a mobile computer, personal computer, and/or server.

In addition, with respect to FIG. 2, in some embodiments of the invention, the HTE module, such as HTE module 202b, may be used in combination with or integrated with a spreader 204, as shown with electronic component 104b. The spreader 204 may include a heat exchanger, a heat sink, with or without various arrangements of fins, blocks, or other surface features to increase the surface area of the spreader 204 and thus increase the transfer of heat. The various designs of spreaders is well-known in the art and one of ordinary skill in the relevant art(s) would appreciate, based at least on the teachings described herein, how to position the HTE module 202b with respect to the spreader 204 to provide for or maximize the enhancement of heat transfer.

Similarly to HTE module 202a, the HTE module 202b may provide, in the locality of the electronic component 104b, an increase in the velocity of the air over the electronic component 104b. The air flow over the electronic component 104a is indicated at 210b. The increase in air velocity may move a larger amount of heat off the electronic component 104b and into the air flow established by the fan 108. In alternative embodiments, the HTE module 202b may be positioned to enhance an air flow in a different direction, such as toward the housing 101 and/or away from any other components of the computer system 200.

In some embodiments, a HTE module 202c may be positioned with respect to the CPU 102. In some embodiments, the CPU 102 may include a microprocessor, a multiple core processor, or the like. The position of the HTE module 202c may be in close proximity to the CPU 102, according to some embodiments of the invention. The HTE module 202c may enhance the heat transfer from the CPU 102 to the air flow 110, which exits the computer system 200 due to the operation of fan 108.

In alternative embodiments of the invention, as one of ordinary skill in the relevant art would appreciate, based at least on the teachings described herein, that the embodiments of the invention do not require more than one HTE module. Furthermore, that one of ordinary skill would appreciate that the heat exchanger 106 and fan 108 may be replaced with alternative primary cooling systems, as are well-known in the art. Indeed, the embodiments of the HTE module may be readily implemented in various cooling systems where an enhancement of air or fluid, such as, but not limited to liquid, flow through a cooling system to transfer heat from electronic components is needed. Additional details regarding the HTE module are now discussed.

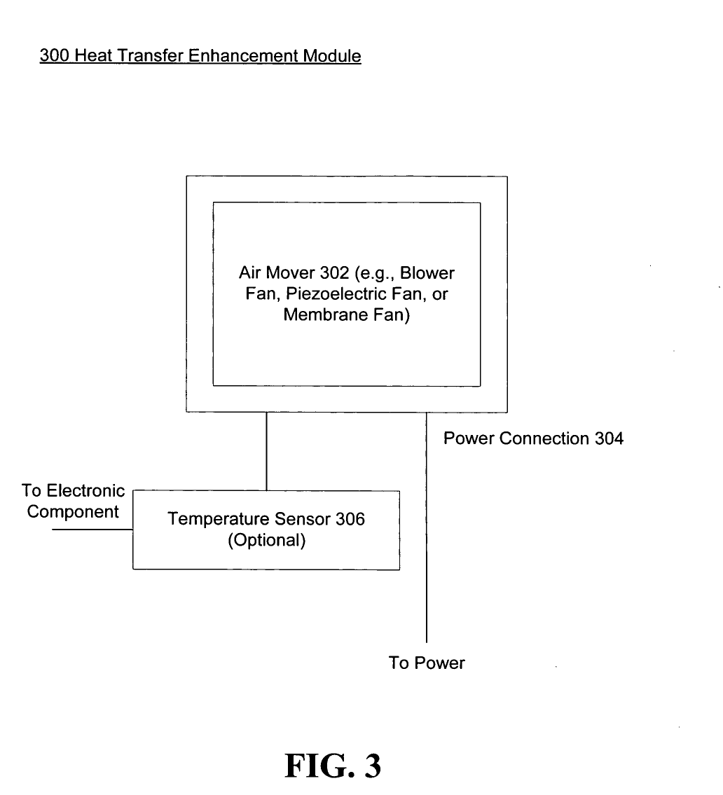

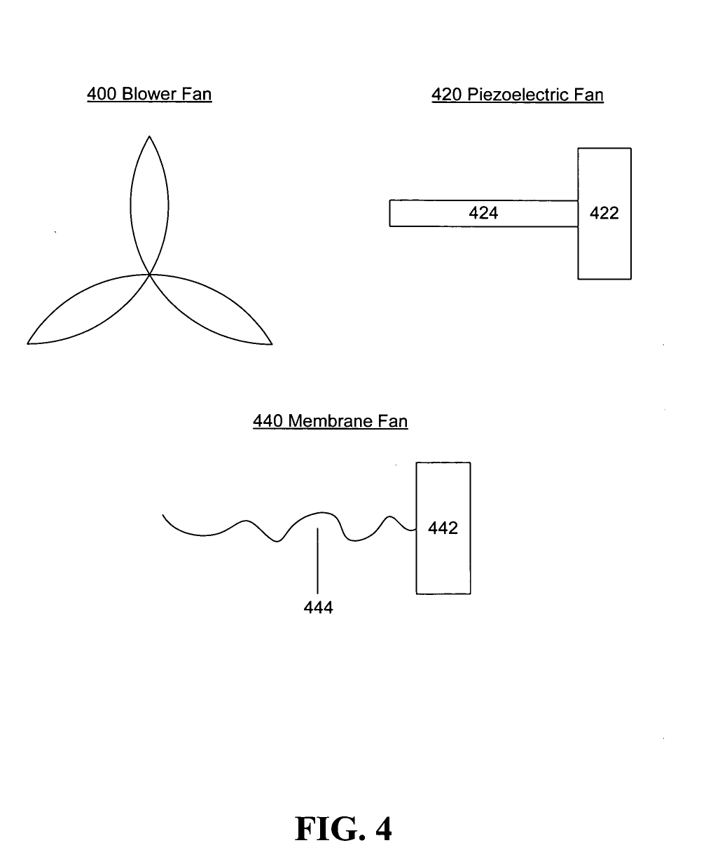

FIG. 3 illustrates an example of a heat transfer enhancement module according to some embodiments of the invention. The HTE module 300 may include an air mover 302, which in some embodiments of the invention may include a blower-type fan, a piezoelectric fan, and/or a membrane fan. Additional details on the types of air mover are discussed below with respect to FIG. 4. In some embodiments of the invention, the air mover 302 may be coupled, either directly or indirectly, to a power source by power connection 304. The power source may be from the computer system or one of its components.

In some embodiments, a temperature sensor 306 may be optionally coupled to the air mover 302. The temperature sensor 306 may be further coupled to the electronic component. In operation, in some embodiments, the temperature sensor 306 may determine a temperature of the electronic component and notify or activate the air mover 302, which may be off, or in a low or high mode of operation, depending on the amount of enhancement (cooling) required. In other embodiments, the temperature sensor may determine the temperature of the chassis skin in the vicinity of the electronic component if its temperature is likely to exceed acceptable limits.

FIG. 4 illustrates examples of fan types according to some embodiments of the invention. The types of air movers may include a blower fan 400, a piezoelectric fan 420, and/or a membrane fan 440. In some embodiments, the blower fan 400 may include two or more blades, such as the three shown in FIG. 4. As one of ordinary skill in the relevant art would appreciate, blower fans may typically have many more blades than the three illustrated at 400. Indeed, in some embodiments, the blower fan 400 may have a dozen or more low profile blades. The operation of blower fans is well-known in the art and one of ordinary skill would appreciate their use in the air mover, such as air mover 302. The piezoelectric fan 420 may include an actuator 422 and a metallic strip 424, according to some embodiments of the invention. In operation, the piezoelectric fan 420 may include having the actuator 422 vibrate at one or more frequencies which results in the metallic strip 424 swing back and forth, thus generating a movement in the surrounding air. In some embodiments, the membrane fan 440 may include an actuator 442 and a membrane 444. In operation, the membrane fan 440 may including having the actuator 442 vibrate at one or more frequencies which results in the membrane 444 sweeping with one or more wave-like oscillations, thus generating a movement in the surrounding air. In some embodiments of the invention, the air mover 302 may include more than one of the type of fans and/or more than one fan. The fan may be placed in a line next to each other, or in parallel, such that the enhancement of heat transfer is affected by the HTE module.

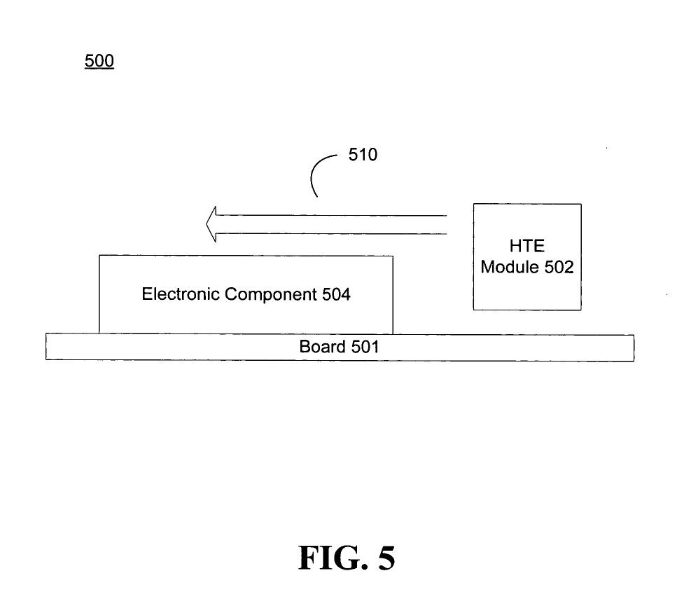

FIG. 5 illustrates an example of a heat transfer enhancement module according to some embodiments of the invention. The operation of the HTE module may be shown in system 500, where HTE module 502 may be positioned to produce an increase in the velocity of the air flow over an electronic component 504, according to some embodiments of the invention. The component 504 and/or HTE module 502 may be coupled to a board 501, such as, but not limited to, a motherboard or part of the housing of the system.

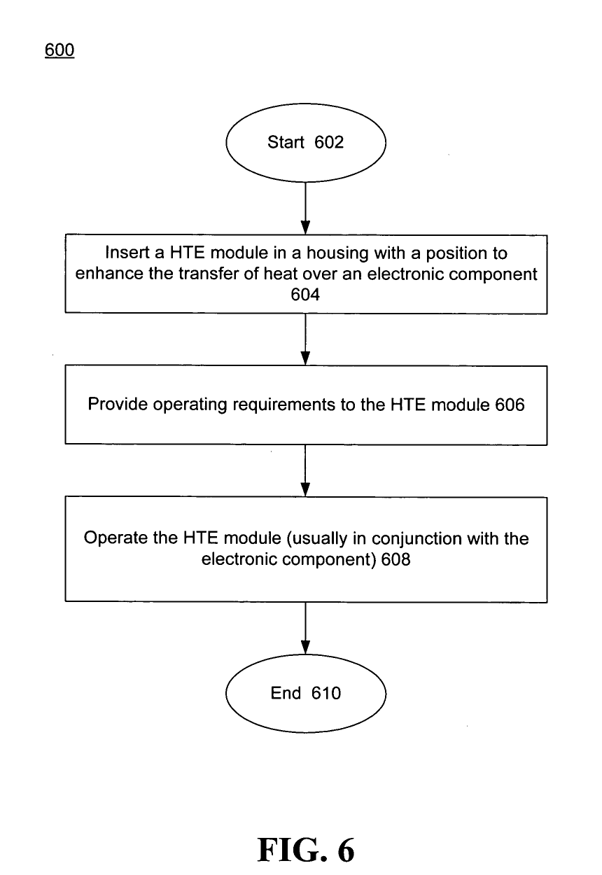

FIG. 6 illustrates an example of the installation and use of the heat transfer enhancement module according to some embodiments of the invention. According to one embodiment of the invention, the method may begin at element 602 and proceed to element 604, where it inserts a HTE module in a housing with a position to enhance the transfer of heat over an electronic component. The housing may be of a computer system in some embodiments of the invention. The position may be at or near the electronic component or integrated with it or a spreader over the electronic component, according to some embodiments of the invention.

The method may then proceed to element 606, where it provides operating requirements to the HTE module. In some embodiments, the HTE module may operate whenever the computer system is operational. The HTE module may be coupled to a temperature sensor and thus may operate at various levels of enhancement depending on the temperatures sensed by the sensor. In some embodiments of the invention, the HTE module may be inactive until a predetermined temperature is reached. The method then proceeds to element 608, where it operates the HTE module. In some embodiments of the invention, the operation is usually in conjunction or combination with the operation of the electronic component.

The method 600 may then proceed to element 610, where it ends and may be repeated as one of ordinary skill in the relevant art would appreciate, based at least on the teachings provided herein. According to some embodiments of the invention, one or more of the elements 604, 606, and/or 608 may occur independently.

Embodiments of the present invention may be described in sufficient detail to enable those skilled in the art to practice the invention. Other embodiments may be utilized, and structural, logical, and intellectual changes may be made without departing from the scope of the present invention. Moreover, it is to be understood that various embodiments of the invention, although different, are not necessarily mutually exclusive. For example, a particular feature, structure, or characteristic described in one embodiment may be included within other embodiments. Those skilled in the art can appreciate from the foregoing description that the techniques of the embodiments of the invention can be implemented in a variety of forms. Therefore, while the embodiments of this invention have been described in connection with particular examples thereof, the true scope of the embodiments of the invention should not be so limited since other modifications will become apparent to the skilled practitioner upon a study of the drawings, specification, and following claims.

What is claimed is:

1. An apparatus comprising:
a heat transfer enhancement module internally coupled to an electronic device and positioned in close proximity to an electronic component, wherein the heat transfer enhancement module includes an air mover to enhance heat transfer of the electronic component, and wherein the air mover is not a primary air mover of the electronic device.

2. The apparatus of claim 1, further comprising:
a power connection to receive electrical power from the computing system to power the heat transfer enhancement module.

3. The apparatus of claim 1, further comprising:
a temperature sensor in contact with or in the vicinity of the electronic component, wherein the temperature sensor is preset to activate the heat transfer enhancement module.

4. The apparatus of claim 1, wherein the air mover is a blower fan, a piezoelectric fan, and/or a membrane fan.

5. The apparatus of claim 4, wherein the air mover includes more than one of the blower fan, the piezoelectric fan, and/or the membrane fan.

6. The apparatus of claim 1, wherein the electronic component includes a spreader or heat exchanger.

7. The apparatus of claim 6, wherein the heat transfer enhancement module is integrated into the spreader or the heat exchanger.

8. The apparatus of claim 1, wherein heat transfer enhancement module is coupled to the electronic component.

9. The apparatus of claim 1, wherein the electronic component is one of a memory, a hard drive, a network card, a video graphics card, a motherboard, and/or a heat source.

10. The apparatus of claim 1, wherein the electronic device is one of a mobile computer.

11. A computer system comprising:
a housing; and
a heat transfer enhancement module internally coupled to an electronic device and positioned in close proximity to an electronic component, wherein the heat transfer enhancement module includes an air mover to enhance heat transfer of the electronic component, and wherein the air mover is not a primary air mover of the electronic device.

12. The computer system of claim 11, further comprising:
a power connection to receive electrical power from the system to power the heat transfer enhancement module.

13. The computer system of claim 11, further comprising:
a temperature sensor on or in the vicinity of the electronic component, wherein the temperature sensor is preset to activate the heat transfer enhancement module.

14. The computer system of claim 11, wherein the air mover is a blower fan, a piezoelectric fan, and/or a membrane fan.

15. The system of claim 14, wherein the air mover includes more than one of the blower fan, the piezoelectric fan, and/or the membrane fan.

16. The computer system of claim 11, wherein the electronic component includes a spreader or heat exchanger.

17. The computer system of claim 16, wherein the heat transfer enhancement module is integrated into the spreader or the heat exchanger.

18. The computer system of claim 11, wherein heat transfer enhancement module is coupled to the electronic component.

19. The computer system of claim 11, wherein the electronic component is one of a memory, a hard drive, a network card, a video graphics card, a motherboard, and/or a heat source.

20. The computer system of claim 11, wherein the electronic device is one of a mobile computer.

21. The computer system of claim 11, wherein the primary heat exchanger includes a blower fan and operates to provide air flow for the system.

22. A method comprising:
inserting a heat transfer enhancement module in a housing of an electronic device with a position to move air over an electronic component; and
providing one or more operating requirements to the heat transfer enhancement module.

23. The method of claim 22, further comprising:
operating the heat transfer enhancement module to move air over the electronic component.

24. The method of claim 22, wherein the one or more operating requirements are provided to a temperature sensor at the heat transfer enhancement module.

25. The method of claim 22, wherein the electronic component is one of a central processing unit, a processor, a memory, a hard drive, a network card, a video graphics card, a motherboard, and/or a heat source.

26. The method of claim 22, wherein the electronic device is one of a mobile computer, personal computer, and/or server.
